(19) United States
(12) Patent Application Publication
(10) Pub. No.: US 2009/0045442 A1
(43) Pub. Date: Feb. 19, 2009

(54) SOLID STATE IMAGING DEVICE AND METHOD FOR FABRICATING THE SAME

(76) Inventors: Naoto Niisoe, Toyama (JP); Kazuhisa Hirata, Kyoto (JP); Tohru Yamada, Tokyo (JP)

Correspondence Address: MCDERMOTT WILL & EMERY LLP, 600 13TH STREET, NW, WASHINGTON, DC, 20005-3096, US

(21) Appl. No.: 12/162,561

(22) PCT Filed: Dec. 6, 2006
(86) PCT No.: PCT/JP2006/324789

§ 371 Date: Jul. 29, 2008

(30) Foreign Application Priority Data
Jan. 30, 2006 (JP) 2006-020294

(51) Int. Cl. H01L 31/00; H01L 21/00

(52) U.S. Cl. 257/292; 438/69; 257/E31.001; 257/E21.001

(57) ABSTRACT

A first oxide film (102) and a first nitride film (103) are formed over a semiconductor substrate (101) so as to be stacked in this order. A plurality of first gate electrodes (104) are arranged on the first nitride film (103) so as to be spaced apart from one another with a predetermined distance therebetween. Upper part and side walls of each of the first gate electrode (104) is covered by a second oxide film (105). The second oxide film (105) and part of the first nitride film (103) located between the first gate electrodes (104) are covered by the second nitride film (106). A plurality of second gate electrodes (107) are formed on at least part of the second nitride film (106) located between adjacent two of the first gate electrodes (104). Each of the second gate electrodes (107) is separated from the first gate electrode (104) by the second oxide film (105) and the second nitride film (106) and separated from the semiconductor substrate (101) by the first oxide film (102), the first nitride film (103) and the second nitride film (106).

### TECHNICAL FIELD

The present invention relates to a solid state imaging device and a method for fabricating the solid state imaging device, and more particularly relates to a solid state imaging device having improved characteristics for achieving excellent saturated charge amount and transfer efficiency and a method for fabricating the solid state imaging device.

### BACKGROUND ART

In general, a solid state imaging device includes a plurality of pixel portions each including a plurality of pixels arranged in a matrix. Each pixel includes a photoreceptor portion configured to output an electric signal according to an amount of incident light and a transfer portion configured to sequentially transfer stored charges. The photoreceptor portion and the transfer portion are provided on a principal surface of a semiconductor substrate.

A structure of a transfer portion of a typical known solid state imaging device and a method for forming the transfer portion will be described with reference to FIGS. 5(a) through 5(e).

First, as shown in FIG. 5(a), a silicon oxide film 12 and a silicon nitride film 13 are formed over a semiconductor substrate 11 so as to be stacked in this order and then a polysilicon layer 14A is formed over the semiconductor substrate 11.

Next, as shown in FIG. 5(b), the polysilicon layer 14A is patterned using lithography and etching, thereby forming a first gate electrode 14. In this patterning, a certain amount of reduction in film thickness occurs due to etching in part of the silicon nitride film 13 other than part thereof located under the first gate electrode 14.

Next, as shown in FIG. 5(c), polysilicon forming the first gate electrode 14 is thermally oxidized, thereby forming a silicon oxide film 15 on upper part and side walls of the first gate electrode 14. Because of a difference between an oxide film growth rate on the silicon nitride film 13 and an oxide film growth rate on the polysilicon film forming the first gate electrode 14, a surface of the silicon nitride film 13 is hardly oxidized.

Next, as shown in FIG. 5(d), a polysilicon layer 16A is formed over the semiconductor substrate 11.

Next, as shown in FIG. 5(e), the polysilicon layer 16A is patterned using lithography and etching, thereby forming a second gate electrode 16 partially overlapping with the first gate electrode 14.

The above-described known solid state imaging device has the following problems. FIGS. 6(a) and 6(b) are cross-sectional views for explaining the problems of the structure of the transfer portion of the known solid state imaging device.

First, the second gate electrode 16 is electrically separated by the silicon oxide film 15 and overlaps with the first gate electrode 14. As described above, a difference in oxide film growth rate between the silicon nitride film 13 and the polysilicon film forming the first gate electrode 14 is utilized to form the silicon oxide film 15. Thus, as shown in FIG. 6(a), a thickness of the silicon oxide film 15 interposed between the first gate electrode 14 and the second gate electrode 16 is smaller in parts thereof located on lower parts of the side walls of the first gate electrode 14 than in other parts thereof. Accordingly, an inter-gate leakage current is easily generated in the parts of the silicon oxide film 15 located on the lower parts of the side walls of the first gate electrode 14.

Second, due to etching performed in forming the first gate electrode 14, a film thickness is reduced by a certain amount in part of the silicon nitride film 13 other than the part thereof located under the first gate electrode 14. Accordingly, the part of the silicon nitride film 13 located under the first gate electrode 14 and part of the silicon nitride film 13 located under the second gate electrode 16 have different thicknesses. As a result, a dielectric capacitance between the first gate electrode 14 and the semiconductor substrate 11 and a dielectric capacitance between the second gate electrode 16 and the semiconductor substrate 11 differ from each other. Therefore, as shown in FIG. 6(b), a potential under each gate electrode varies, and degradation of characteristics such as reduction in a saturated charge amount for charges to be stored and reduction in transfer efficiency are caused. In FIG. 6(b), VL and VM denote voltage levels applied to the gate electrodes, respectively.

To cope with the above-described problems, as described in Patent Reference 1, a technique characterized in that after removal of a silicon nitride film, a silicon nitride film is newly formed has been proposed.

Hereafter, a solid state imaging device described in Patent Reference 1 and a method for fabricating the solid state imaging device will be described with reference to FIGS. 7(a) through 7(g).

First, as shown in FIG. 7(a), a silicon oxide film 22 and a silicon nitride film 23 are formed over a semiconductor substrate 21 so as to be stacked in this order and then a polysilicon layer 24A is formed over the semiconductor substrate 21.

Next, as shown in FIG. 7(b), the polysilicon layer 24A is patterned using lithography and etching, thereby forming a first gate electrode 24. In this patterning, a certain amount of reduction in film thickness occurs due to etching in part of the silicon nitride film 23 other than part thereof located under the first gate electrode 24.

Next, as shown in FIG. 7(c), polysilicon forming the first gate electrode 24 is thermally oxidized, thereby forming a silicon oxide film 25 on upper part and side walls of the first gate electrode 24. Because of a difference between an oxide film growth rate on the silicon nitride film 23 and an oxide film growth rate on the polysilicon film forming the first gate electrode 24, a surface of the silicon nitride film 23 is hardly oxidized.

Next, as shown in FIG. 7(d), the part of the silicon nitride film 23 other than the part thereof located under the first gate electrode 24 is removed by wet etching using phosphoric acid which is highly selective with respect to the silicon oxide film 25.

Next, as shown in FIG. 7(e), a silicon nitride film 26 is formed over the semiconductor substrate 21 so as to have the same thickness as the thickness of the part of the silicon nitride film 23 located under the first gate electrode 24.

Next, as shown in FIG. 7(f), a polysilicon layer 27A is formed over the semiconductor substrate 21.

Next, as shown in FIG. 7(g), the polysilicon layer 27A is patterned using lithography and etching, thereby forming a second gate electrode 27 partially overlapping with the first gate electrode 24.

In the above-described solid state imaging device of Patent Reference 1, an interlevel film for electrically separating the first gate electrode 24 and the second gate electrode 27 from each other is formed of the silicon oxide film 25 and the silicon nitride film 26. Thus, an inter-gate leakage current is hardly generated. Moreover, part of the silicon nitride film 23 located under the first gate electrode 24 has the same thickness as a thickness of part of the second nitride film 26 located under the second gate electrode 27. Therefore, a potential difference under the gate electrodes can be prevented, so that excellent transfer efficiency can be achieved.

[Patent Reference 1]

Japanese Laid-Open Publication No. 6-85234

[Patent Reference 2]

Japanese Laid-Open Publication No. 4-335572

[Patent Reference 3]

Japanese Laid-Open Publication No. 5-267355

### DISCLOSURE OF THE INVENTION

### Problems that the Invention is to Solve

However, the solid state imaging device of Patent Reference 1 has the following problems. FIG. 8 is a cross-sectional view for explaining the problems of a structure of a transfer portion of the solid state imaging device of Patent Reference 1.

First, in fabricating the solid state imaging device of Patent Reference 1, after exfoliation of the part of the silicon nitride film 23 other than the part thereof located under the first gate electrode 24, the silicon nitride film 26 is newly formed. Thus, a film such as a natural oxide film is formed at an interface between the part of the silicon nitride film 23 located under the first gate electrode 24 and the silicon nitride film 26. As a result, the silicon nitride film 23 and the silicon nitride film 26 can not form a continuous film, so that reduction in transfer efficiency is caused.

Second, when an etching amount varies in exfoliating the silicon nitride film 23, the part of the silicon nitride film 23 located under the first gate electrode 24 is removed as well. Therefore, if coverage of the silicon nitride film 26 which has been newly formed is poor, as shown in FIG. 8, voids 28 are generated at the interface between the silicon nitride film 23 and the silicon nitride film 26. As a result, a breakdown voltage between the first gate electrode 24 and the second gate electrode 27 and a breakdown voltage between the first gate electrode 24 and the semiconductor substrate 21 are reduced, so that a leakage current is generated.

Third, in a method for fabricating the solid state imaging device of Patent Reference 1, heat treatment at 850° C. or more is performed to the silicon nitride film 23 for at least one time more than the number of heat treatment to the silicon nitride film 26. Thus, influence of baking on film quality differs between the silicon nitride film 23 and the silicon nitride film 26. Specifically, in the solid state imaging device of Patent Reference 1, even if the thickness of the part of the silicon nitride film 23 located under the first gate electrode 24 and the thickness of the part of the silicon nitride film 26 located under the second gate electrode 27 are the same, the silicon nitride films are not electrically the same. Therefore, respective potentials under the gate electrodes differ from each other, so that reduction in transfer efficiency is caused.

In view of the above-described problems, the present invention has been devised and it is therefore an object of the present invention to provide a solid state imaging device having an improved characteristic for achieving excellent saturated charge amount and transfer efficiency and a method for fabricating the solid state imaging device.

### Solution to the Problems

To achieve the above-described object, the present inventors conducted various examinations and found as a result of the examinations that even after formation of a first gate electrode, if part of a silicon nitride film (which will be hereafter referred to as a “first nitride film”) other than part thereof located under the first gate electrode is not exfoliated but is kept remaining and another silicon nitride film (which will be hereafter referred to as a “second nitride film”) is formed so as to compensate reduction in thickness of the first nitride film, the problems of the solid state imaging device of Patent Reference 1 can be overcome.

Specifically, a solid state imaging device according to the present invention includes: a semiconductor substrate; a first oxide film and a first nitride film formed over the semiconductor substrate so as to be stacked in this order; a plurality of first gate electrodes arranged on the first nitride film so as to be spaced apart from one another with a predetermined distance therebetween; a second oxide film formed so as to cover upper part and side walls of each of the first gate electrodes; a second nitride film formed so as to cover the second oxide film and part of the first nitride film located between the first gate electrodes; and a plurality of second gate electrodes formed on at least part of the second nitride film located between adjacent two of the first gate electrodes. Each of the second gate electrodes is separated from an associated one of the first gate electrodes by the second oxide film and the second nitride film and is separated from the semiconductor substrate by the first oxide film, the first nitride film and the second nitride film.

A method for fabricating a solid state imaging device according to the present invention includes: a first step of forming a first oxide film and a first nitride film over a semiconductor substrate so that the first oxide film and the first nitride film are stacked in this order; a second step of forming, on the first nitride film, a plurality of first gate electrodes so that the first gate electrodes are arranged so as to be spaced apart from one another with a predetermined distance therebetween; a third step of forming a second oxide film so that the second oxide film covers upper part and side walls of each of the first gate electrodes; a fourth step of forming a second nitride film so that the second nitride film covers the second oxide film and part of the first nitride film located between the first gate electrodes; and a fifth step of forming a plurality of second gate electrodes on at least part of the second nitride film located between adjacent two of the first gate electrodes.

### EFFECTS OF THE INVENTION

According to the present invention, part of the first nitride film other than part thereof located under each of the first gate electrodes is not removed and the second nitride film is formed so as to have a thickness corresponding to the amount of reduction in film thickness of the first nitride film in a previous process step such as etching. Thus, a nitride film located under each of the first gate electrodes and a nitride film located under each of the second gate electrodes can be formed of a continuous film to which the same heat treatment has been performed. Therefore, a solid state imaging device having excellent transfer efficiency can be obtained.

According to the present invention, at a time of formation of the second nitride film, the part of the first nitride film other than the part thereof located under each of the first gate electrodes is kept remaining. Thus, the generation of a void between the nitride film located under each of the first gate electrodes and the nitride film located under an associated one of the second gate electrodes can be avoided. Therefore, reduction in a breakdown voltage between each of the first gate electrodes and an associated one of the second gate electrodes and a breakdown voltage between each of the first gate electrodes and the semiconductor substrate can be prevented, so that a leakage current is hardly generated.

According to the present invention, a thickness of part of the nitride film located under each of the first gate electrodes and a thickness of part of the nitride film located under each of the second gate electrodes can be set to be the same. Thus, the generation of a difference between potentials under the gate electrodes can be prevented, so that excellent saturated charge amount and transfer efficiency can be maintained.

According to the present invention, each of the first gate electrodes and an associated one of the second gate electrodes are electrically separated from each other by the second oxide film and the second nitride film. Thus, an inter-gate breakdown voltage is improved, so that a leakage current is much less likely to be generated. Since a dielectric constant of a nitride film is about the double of a dielectric constant of an oxide film, an effective thickness of an interlevel film can be reduced. Therefore, excellent transfer efficiency can be ensured.

### BRIEF DESCRIPTION OF THE DRAWINGS

FIG. 1 is an overall view of a solid state imaging device according to first and second embodiments of the present invention.

FIGS. 2(a) through 2(f) are cross-sectional views illustrating respective steps of a method for fabricating a solid state imaging device according to the first embodiment of the present invention.

FIGS. 3(a) through 3(f) are cross-sectional views illustrating respective steps of a method for fabricating a solid state imaging device according to the second embodiment of the present invention.

FIGS. 4(a) through 4(d) are cross-sectional views illustrating respective steps of a method for fabricating a solid state imaging device according to the second embodiment of the present invention.

FIGS. 5(a) through 5(e) are cross-sectional views illustrating respective steps of a known method for fabricating a solid state imaging device.

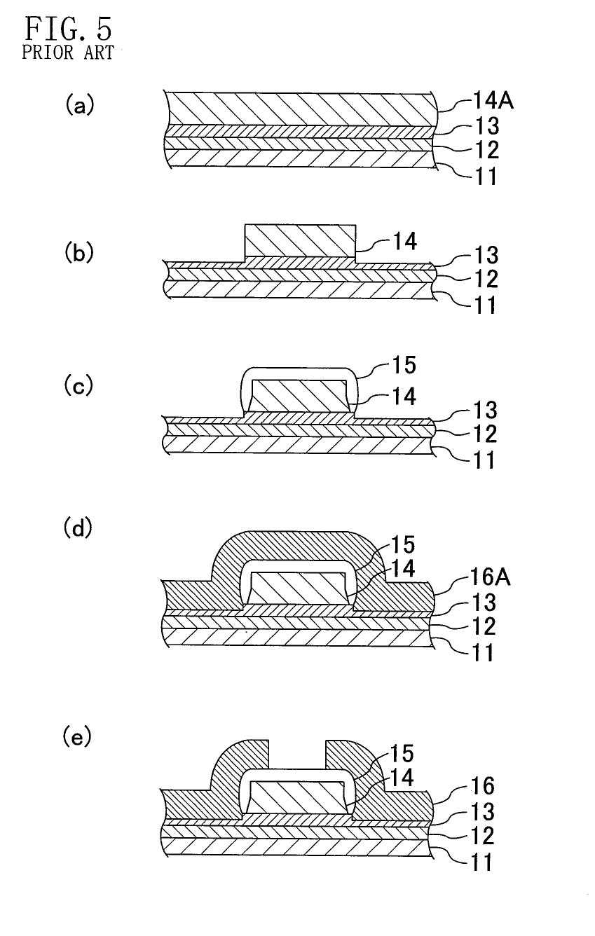

FIGS. 6(a) and 6(b) are cross-sectional views for explaining problems of the known solid state imaging device.

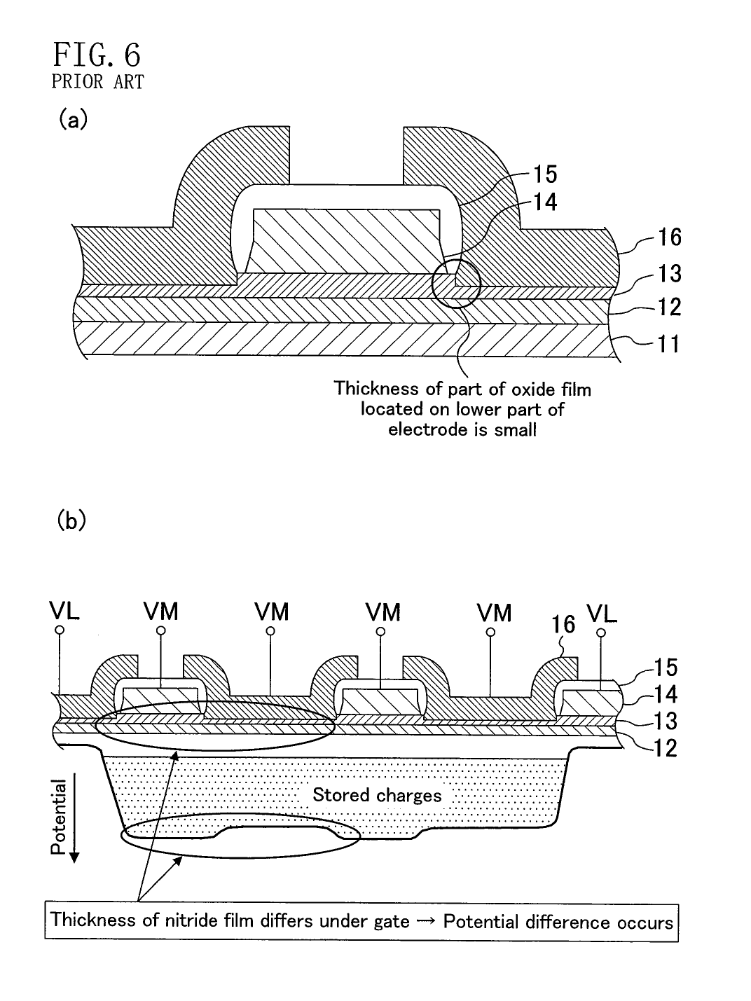

FIGS. 7(a) through 7(g) are cross-sectional views illustrating respective steps of another known method for fabricating a solid state imaging device.

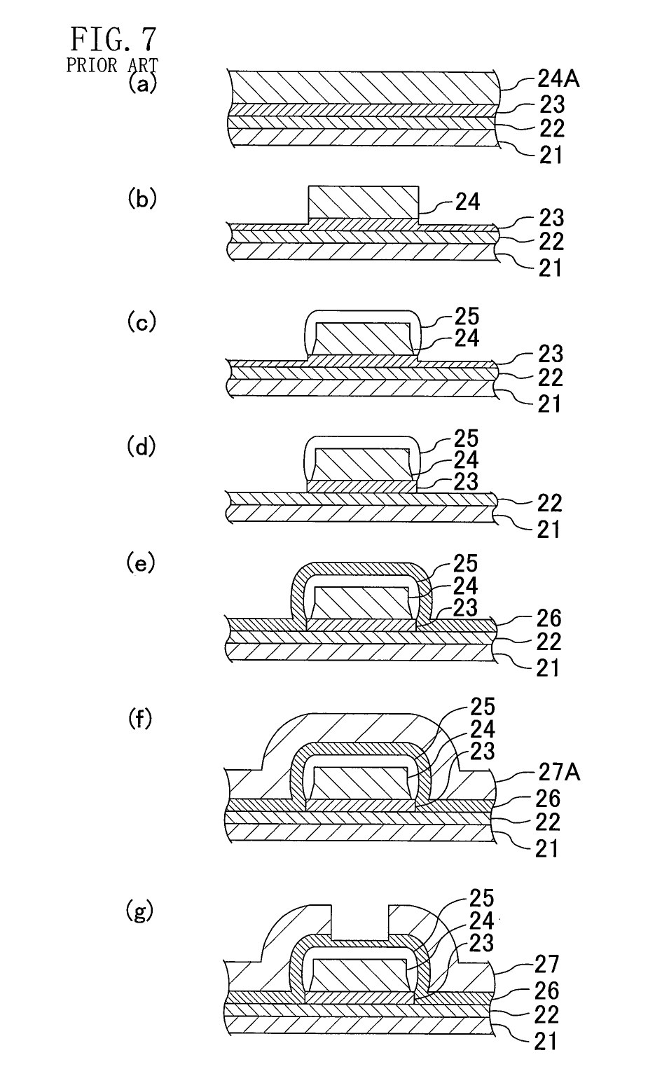

FIG. 8 is a cross-sectional view for explaining problems of another solid state imaging device.

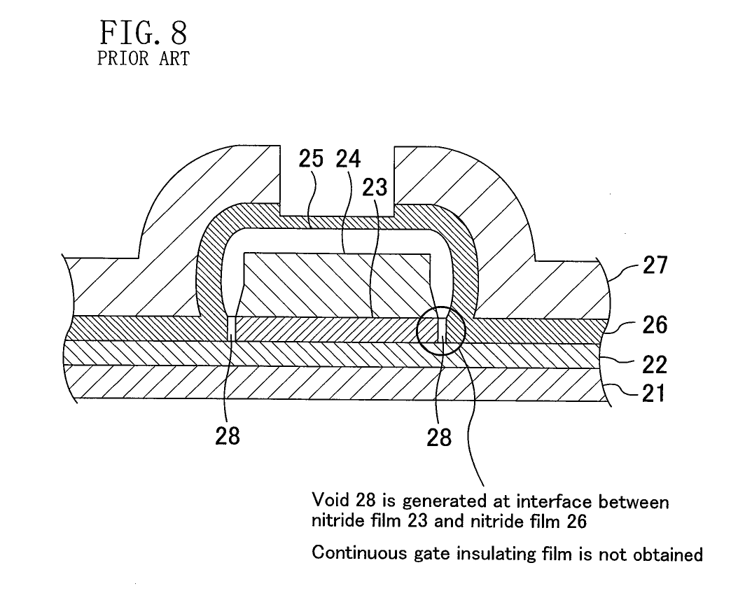

### EXPLANATION OF REFERENCE NUMERALS

1 Pixel section
2 Photodiode
3 Vertical transfer portion
4 Horizontal transfer portion
5 Output portion
101 Semiconductor substrate
102 First oxide film
103 First nitride film
104 First gate electrode
104A Polysilicon film
105 Second oxide film
106 Second nitride film
107 Second gate electrode
107A Polysilicon film
201 Semiconductor substrate
202 First oxide film
203 First nitride film
204 First gate electrode
204A Polysilicon film
205 Second oxide film
206 Second nitride film
207 Second gate electrode
207A Polysilicon film
208 Third oxide film
209 Third nitride film
210 Third gate electrode
210A Polysilicon film

### BEST MODE FOR CARRYING OUT THE INVENTION

### First Embodiment

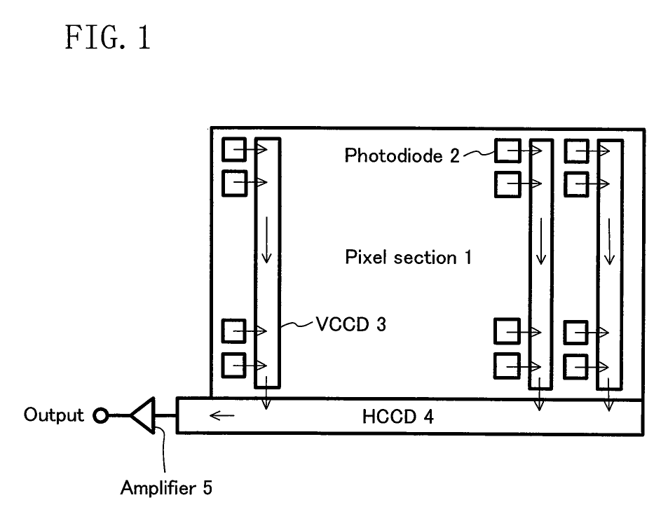

Hereafter, a solid state imaging device according to a first embodiment of the present invention and a method for fabricating the solid state imaging device will be described in detail with reference to the accompanying drawings. FIG. 1 is an overall view of a solid state imaging device according to this embodiment. As shown in FIG. 1, the solid state imaging device of this embodiment includes a pixel section each including a plurality of pixels arranged in a matrix and a peripheral circuit section provided around the pixel section. In a pixel section 1, photoreceptor portions (photodiodes) 2 each of which is configured to output an electric signal according to an incident light amount and vertical transfer portions (VCCD) 3 each of which is configured to sequentially transfer charges stored in the photodiode 2 in the vertical direction are provided. In the peripheral circuit section, a horizontal transfer portion (HCCD) 4 configured to sequentially transfer charges transferred from the vertical transfer portions 3 in the horizontal direction and an output portion (amplifier) 5 for detecting charges transferred from the horizontal transfer portion 4 and amplifying detected charges are provided.

The principle of operation of the solid state imaging device of this embodiment will be described. Incident light is photoelectric-converted by the photodiode 2, stored for a certain amount of time, and then sent to the transfer portions 3 and 4. In the transfer portions 3 and 4, utilizing a depth of a depletion layer formed in the semiconductor substrate, charges are sequentially transferred from one to another among adjacent parts of the semiconductor substrate which are located under electrodes by application of pulse voltages having different phases to transfer electrodes arranged on the semiconductor substrate so as to be spaced apart from one another with a predetermined distance therebetween. Finally, in the output portion 5, the charges are detected and amplified.

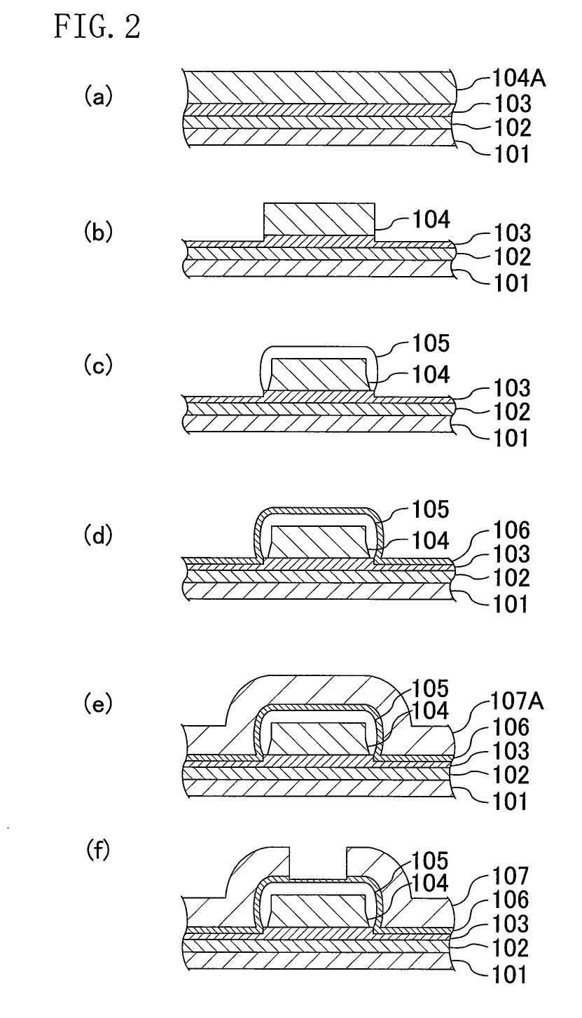

Hereafter, a structure of a transfer portion in the solid state imaging device of this embodiment and a method for forming the transfer portion will be described with reference to FIGS. 2(a) through 2(f). Each transfer portion in the solid state imaging device of this embodiment has a two-layer gate structure. Although only one lower-layer gate electrode (first gate electrode) is illustrated in FIGS. 2(a) through 2(f), a plurality of first gate electrodes are arranged on the semiconductor substrate so as to be spaced apart from one another with a predetermined distance therebetween.

First, as shown in FIG. 2(a), a first oxide film (silicon oxide film) 102 and a first nitride film (silicon nitride film) 103 are formed over a semiconductor substrate 101 so as to be stacked in this order. In this case, the semiconductor substrate 101 may be, for example, a silicon substrate. For example, a p-type or n-type semiconductor layer may be provided on the substrate (hereafter, the substrate including the semiconductor layer will be referred to as the “semiconductor substrate 101”). A channel region is formed at a certain depth from a surface of the semiconductor substrate 101. As the first oxide film 102, for example, a thermally-oxidized film (silicon oxide film) can be used. The thermally-oxidized film is formed, for example, by heat treatment at 850° C. or more so as to have a thickness of about 10-50 nm. As the first nitride film 103, for example, a silicon nitride film can be used. The silicon nitride film is formed, for example, by low pressure CVD (chemical vapor deposition) so as to have a thickness of about 20-100 nm. Next, to form first gate electrodes 104, a conductive film, such as a polysilicon film 104A, is formed on the first nitride film 103.

Next, as shown in FIG. 2(b), the polysilicon film 104A is patterned using lithography and dry etching, thereby forming first gate electrodes 104 on the first nitride film 103. In this patterning, a certain amount of reduction in film thickness occurs due to the etching in part of the first nitride film 103 other than part thereof located under each of the first gate electrodes 104. Although not shown in FIG. 2(b), a plurality of first gate electrodes 104 are formed on the first nitride film 103 so as to be spaced apart from one another with a predetermined distance therebetween.

Next, as shown in FIG. 2(c), polysilicon forming each of the first gate electrodes 104 is thermally oxidized, thereby forming a second oxide film (silicon oxide film) 105 on upper part and side walls of each of the first gate electrodes 104. Because of a difference between an oxide film growth rate on the first nitride film 103 and an oxide film growth rate on the polysilicon film forming each of the first gate electrodes 104, a surface of the first nitride film 103 is hardly oxidized.

Next, as shown in FIG. 2(d), a second nitride film 106 is formed over the semiconductor substrate 101 so as to have a thickness corresponding to the amount of reduction in film thickness of the first nitride film 103 due to the etching. Thus, the second oxide film 105 and part of the first nitride film 103 located between the plurality of first gate electrodes 104 are covered by the second nitride film 106. As the second nitride film 106, for example, a silicon nitride film can be used. The silicon nitride film is formed, for example, by low pressure CVD, so that a thickness of part of the first nitride film 103 located under each of the first gate electrodes 104 and a total of respective thicknesses of parts of the first nitride film 103 and the second nitride film 106 other than the parts thereof located under each of the first gate electrodes 104 are set to be the same.

Next, as shown in FIG. 2(e), to form second gate electrodes 107, for example, a conductive film, such as a polysilicon film 107A, is formed over the semiconductor substrate 101.

Next, as shown in FIG. 2(f), the polysilicon film 107A is patterned using lithography and etching, thereby forming a plurality of second gate electrodes 107 on at least part of the second nitride film 106 located between adjacent two of the first gate electrodes 104. Each of the second gate electrodes 107 is separated from an associated one of the first gate electrodes 104 by the second oxide film 105 and the second nitride film 106 and separated from the semiconductor substrate 101 by the first oxide film 102, the first nitride film 103 and the second nitride film 106.

In this embodiment, the second gate electrodes 107 are formed so that each of the second gate electrodes 107 overlaps with an associated one of the first gate electrodes 104. However, instead of this structure, such an overlapping portion does not have to be provided and the overlapping portion may be removed in a subsequent step.

As has been described, according to this embodiment, the part of the first nitride film 103 other than the part thereof located under the first gate electrode 104 is not removed and the second nitride film 106 is formed so as to have a thickness corresponding to the amount of reduction in film thickness of the first nitride film 103 caused in a previous process step such as etching, so that a nitride film located under each of the first gate electrodes 104 and a nitride film located under each of the second gate electrodes 107 can be formed of a continuous film (i.e., the first nitride film 103) to which the same heat treatment has been performed. Therefore, a solid state imaging device having excellent transfer efficiency can be obtained.

According to this embodiment, at a time of formation of the second nitride film 106, the part of the first nitride film 103 other than the part thereof located under each of the first gate electrodes 104 is kept remaining. Thus, the generation of a void between the nitride film located under each of the first gate electrodes 104 and the nitride film located under an associated one of the second gate electrodes 107 can be avoided. Therefore, reduction in a breakdown voltage between each of the first gate electrodes 104 and an associated one of the second gate electrodes 107 and a breakdown voltage between each of the first gate electrodes 104 and the semiconductor substrate 101 can be prevented, so that a leakage current is hardly generated.

According to this embodiment, a thickness of part of the nitride film located under each of the first gate electrodes 104 and a thickness of part of the nitride film located under each of the second gate electrodes 107 can be set to be the same. Thus, the generation of a difference between potentials under the gate electrodes can be prevented, so that excellent saturated charge amount and transfer efficiency can be maintained.

According to this embodiment, each of the first gate electrodes 104 and an associated one of the second gate electrodes 107 are electrically separated from each other by the second oxide film 105 and the second nitride film 106. Thus, an inter-gate breakdown voltage is improved, so that a leakage current is much less likely to be generated. Since a dielectric constant of a nitride film is about the double of a dielectric constant of an oxide film, an effective thickness of an interlevel film can be reduced. Therefore, excellent transfer efficiency can be ensured.

In this embodiment, as a gate insulating film located under each of the first gate electrodes 104 and the second gate electrodes 107, a two-layer structure (ON structure) including a thermally-oxidized film and a silicon nitride film is used. However, instead of the two-layer structure, a three-layer structure (ONO structure) in which a thermally-oxidized film or a low-pressure CVD oxide film is further formed on the silicon nitride film may be used. Specifically, after formation of the first nitride film 103 and before formation of the first gate electrodes 104, an oxide film may be formed on the first nitride film 103 and, after formation of the second nitride film 106 and before formation of the second gate electrodes 107, an oxide film may be formed on the second nitride film 106.

According to this embodiment, a thickness of the second nitride film 106 formed so as to correspond to the amount of reduction in film thickness of the first nitride film 103 is not particularly limited but, for example, is about 2 nm or more and about 35 nm or less. Specifically, the amount of reduction in film thickness of the first nitride film 103 may be predicted, for example, by a statistical technique and, on the basis of a result of the prediction, the thickness of the second nitride film 106 may be set. Alternatively, the amount of reduction in film thickness of the first nitride film 103 may be actually measured and, on the basis of a result of the measurement, the thickness of the second nitride film 106 can be set.

### Second Embodiment

Hereafter, a solid state imaging device according to a second embodiment of the present invention and a method for fabricating the solid state imaging device will be described in detail with reference to the accompanying drawings. An overall structure of the solid state imaging device of this embodiment is the same as that of the first embodiment shown in FIG. 1.

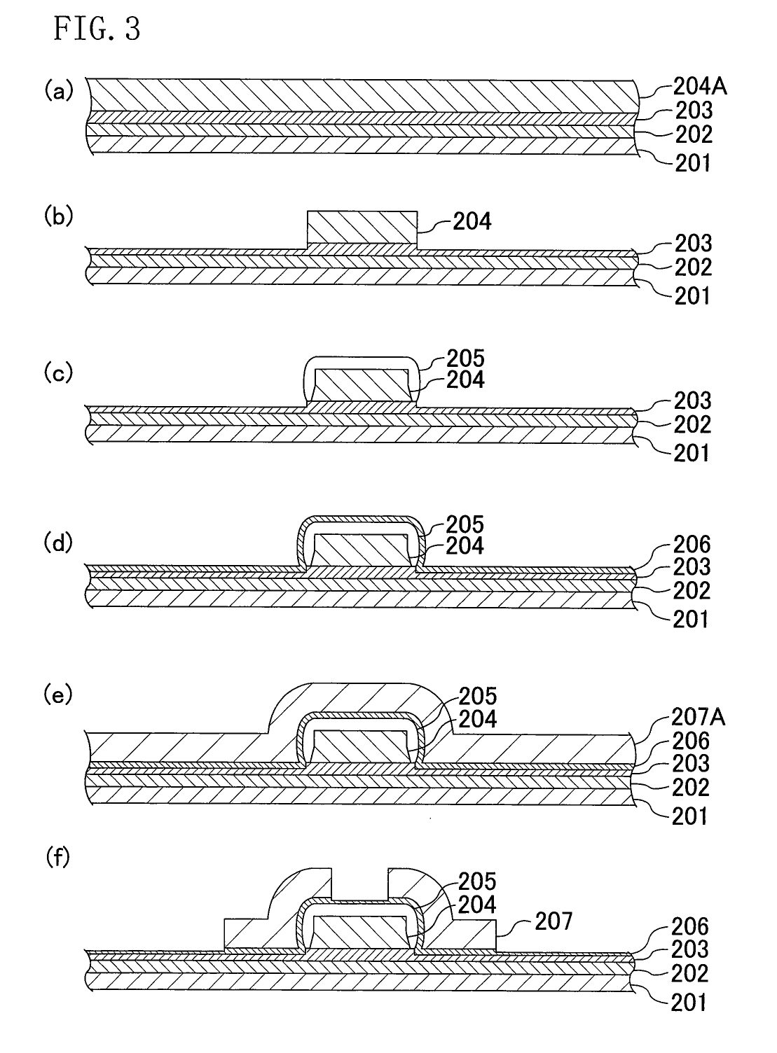

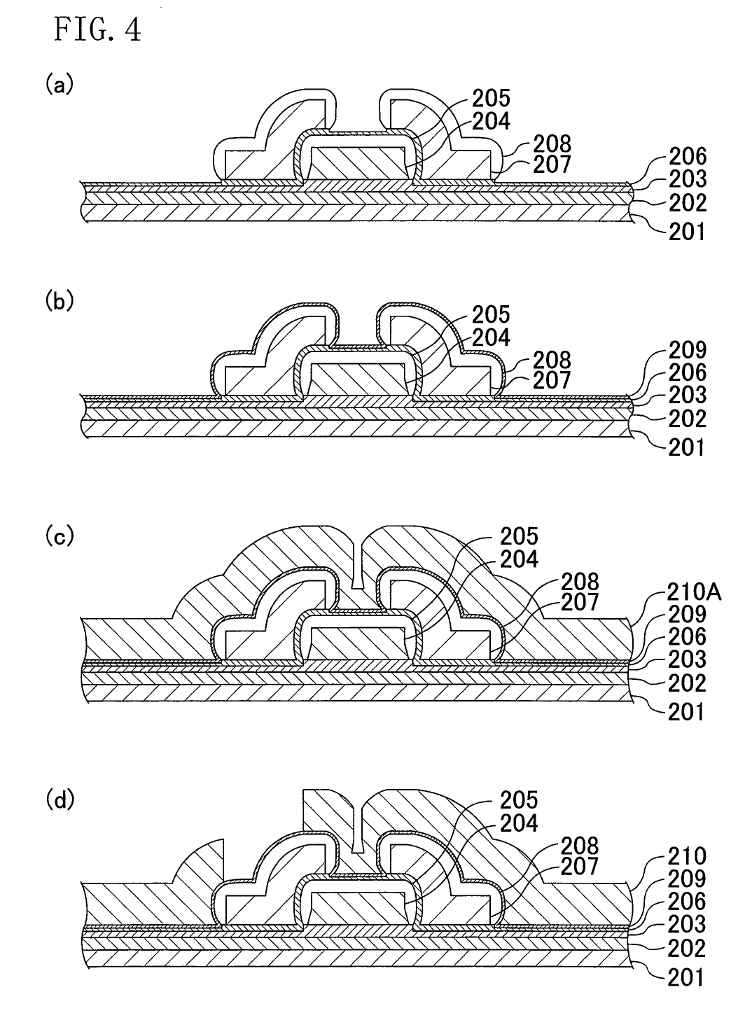

Hereafter, a structure of a transfer portion in the solid state imaging device of this embodiment and a method for forming the transfer portion will be described with reference to FIGS. 3(a) through 3(f) and FIGS. 4(a) through 4(d). Each transfer portion in the solid state imaging device of this embodiment has a three-layer gate structure. Although only one lower-layer gate electrode (first gate electrode) is illustrated in FIGS. 3(a) through 3(f) and FIGS. 4(a) through 4(d), a plurality of first gate electrodes are arranged on a semiconductor substrate so as to be spaced apart from one another with a predetermined distance therebetween.

First, as shown in FIG. 3(a), a first oxide film (silicon oxide film) 202 and a first nitride film (silicon nitride film) 203 are formed over a semiconductor substrate 201 so as to be stacked in this order. In this case, the semiconductor substrate 201 may be, for example, a silicon substrate. For example, a p-type or n-type semiconductor layer may be provided on the substrate (hereafter, the substrate including the semiconductor layer will be referred to as the “semiconductor substrate 201”). A channel region is formed at a certain depth from a surface of the semiconductor substrate 201. As the first oxide film 202, for example, a thermally-oxidized film (silicon oxide film) can be used. The thermally-oxidized film is formed, for example, by heat treatment at 850° C. or more so as to have a thickness of about 10-50 nm. As the first nitride film 203, for example, a silicon nitride film can be used. The silicon nitride film is formed, for example, by low pressure CVD so as to have a thickness of about 20-100 nm. Next, to form first gate electrodes 204, a conductive film, such as a polysilicon film 204A, is formed on the first nitride film 203.

Next, as shown in FIG. 3(b), the polysilicon film 204A is patterned using lithography and dry etching, thereby forming first gate electrodes 204 on the first nitride film 203. In this patterning, a certain amount of reduction in film thickness occurs due to the etching in part of the first nitride film 203 other than part thereof located under each of the first gate electrodes 204. Although not shown in FIG. 3(b), a plurality of first gate electrodes 204 are formed on the first nitride film 203 so as to be spaced apart from one another with a predetermined distance therebetween.

Next, as shown in FIG. 3(c), polysilicon forming each of the first gate electrodes 204 is thermally oxidized, thereby forming a second oxide film (silicon oxide film) 205 on upper part and side walls of each of the first gate electrodes 204. Because of a difference between an oxide film growth rate on the first nitride film 203 and an oxide film growth rate on the polysilicon film forming each of the first gate electrodes 204, a surface of the first nitride film 203 is hardly oxidized.

Next, as shown in FIG. 3(d), a second nitride film 206 is formed over the semiconductor substrate 201 so as to have a thickness corresponding to the amount of reduction in film thickness of the first nitride film 203 due to the etching. Thus, the second oxide film 205 and part of the first nitride film 203 located between the plurality of first gate electrodes 204 are covered by the second nitride film 206. As the second nitride film 206, for example, a silicon nitride film can be used. The silicon nitride film is formed, for example, by low pressure CVD, so that a thickness of part of the first nitride film 203 located under each of the first gate electrodes 204 and a total of respective thicknesses of parts of the first nitride film 203 and the second nitride film 206 other than the parts thereof located under each of the first gate electrodes 204 are set to be the same.

Next, as shown in FIG. 3(e), to form second gate electrodes 207, for example, a conductive film, such as a polysilicon film 207A, is formed over the semiconductor substrate 201.

Next, as shown in FIG. 3(f), the polysilicon film 207A is patterned using lithography and etching, thereby forming a plurality of second gate electrodes 207 on at least part of the second nitride film 206 located between adjacent two of the first gate electrodes 204. Each of the second gate electrodes 207 is separated from an associated one of the first gate electrodes 204 by the second oxide film 205 and the second nitride film 206 and separated from the semiconductor substrate 201 by the first oxide film 202, the first nitride film 203 and the second nitride film 206. In part of the second nitride film 206 other than part thereof located under the second gate electrode 207, a certain amount of reduction in film thickness occurs due to the etching.

In this embodiment, the second gate electrodes 207 are formed so that each of the second gate electrodes 207 overlaps with an associated one of the first gate electrodes 204. However, instead of this structure, such an overlapping portion does not have to be provided and the overlapping portion may be removed in a subsequent step.

Next, as shown in FIG. 4(a), polysilicon forming each of the second gate electrodes 207 is thermally oxidized, thereby forming a third oxide film (silicon oxide film) 208 on upper part and side walls of each of the second gate electrodes 207. Because of a difference between an oxide film growth rate on the second nitride film 206 and an oxide film growth rate on the polysilicon film forming each of the second gate electrodes 207, a surface of the second nitride film 206 is hardly oxidized.

Next, as shown in FIG. 4(b), a third nitride film 209 is formed over the semiconductor substrate 201 so as to have a thickness corresponding to the amount of reduction in film thickness of the second nitride film 206 due to the etching. Thus, the third oxide film 208 and part of the second nitride film 206 located between the plurality of second gate electrodes 207 are covered by the third nitride film 209. As the third nitride film 209, for example, a silicon nitride film can be used. The silicon nitride film is formed, for example, by low pressure CVD, so that a thickness of part of the first nitride film 203 located under each of the first gate electrodes 204 and a total of respective thicknesses of parts of the first nitride film 203, the second nitride film 206 and the third nitride film 209 other than the parts thereof located under each of the second gate electrodes 207 (accurately, under a third gate electrode 210 which will be later described) are set to be the same.

Next, as shown in FIG. 4(c), to form third gate electrodes 210, for example, a conductive film, such as a polysilicon film 210A, is formed over the semiconductor substrate 201.

Next, as shown in FIG. 4(d), the polysilicon film 210A is patterned using lithography and etching, thereby forming a plurality of third gate electrodes 210 on at least part of the third nitride film 209 located between adjacent two of the second gate electrodes 207. Each of the third gate electrodes 210 is separated from an associated one of the second gate electrodes 207 by the third oxide film 208 and the third nitride film 209 and separated from the semiconductor substrate 201 by the first oxide film 202, the first nitride film 203, the second nitride film 206 and the third nitride film 209.

In this embodiment, the third gate electrodes 210 are formed so that each of the third gate electrodes 210 overlaps with an associated one of the second gate electrodes 207. However, instead of this structure, such an overlapping portion does not have to be provided and the overlapping portion may be removed in a subsequent step.

As has been described, according to this embodiment, without removal of the part of the first nitride film 203 other than the part thereof located under each of the first gate electrodes 204 and the part of the second nitride film 206 other than the part of thereof located under each of the second gate electrodes 207, the second nitride film 206 is newly formed so as to have a thickness corresponding to the amount of reduction in film thickness of the first nitride film 203 caused in a previous process step such as etching and the third nitride film 209 is newly formed so as to have a thickness corresponding to the amount of reduction in film thickness of the second nitride film 206 caused in a previous process step such as etching. Thus, a nitride film located under each of the first gate electrodes 204, a nitride film located under each of the second gate electrodes 207 and a nitride film located under each of the third gate electrodes 210 can be formed of a continuous film (i.e., the first nitride film 203) to which the same heat treatment has been performed. Therefore, a solid state imaging device having excellent transfer efficiency can be obtained.

According to this embodiment, at a time of formation of the second nitride film 206, the part of the first nitride film 203 other than the part thereof located under each of the first gate electrodes 204 is kept remaining. Thus, the generation of a void between the nitride film located under each of the first gate electrodes 204 and the nitride film located under an associated one of the second gate electrodes 207 can be avoided. Therefore, reduction in a breakdown voltage between each of the first gate electrodes 204 and an associated one of the second gate electrodes 207 and a breakdown voltage between each of the first gate electrodes 204 and the semiconductor substrate 201 can be prevented, so that a leakage current is hardly generated.

According to this embodiment, at a time of formation of the third nitride film 209, the part of the second nitride film 206 other than the part thereof located in each of the second gate electrodes 207 is kept remaining. Thus, the generation of a void between the nitride film located under each of the second gate electrodes 207 and the nitride film located under an associated one of the third gate electrodes 210 can be avoided. Therefore, reduction in a breakdown voltage between each of the second gate electrodes 207 and an associated one of third gate electrodes 210 and a breakdown voltage between each of the second gate electrodes 207 and the semiconductor substrate 201 can be prevented, so that a leakage current is hardly generated.

According to this embodiment, a thickness of part of the nitride film located under each of the first gate electrodes 204, a thickness of part of the nitride film located under each of the second gate electrodes 207 and a thickness of the nitride film third gate electrodes 210 can be set to be the same. Thus, the generation of a difference between potentials under the gate electrodes can be prevented, so that excellent saturated charge amount and transfer efficiency can be maintained.

According to this embodiment, each of the first gate electrodes 204 and an associated one of the second gate electrodes 207 are electrically separated from each other by the second oxide film 205 and the second nitride film 206 and each of the second gate electrodes 207 and an associated one of the third gate electrodes 210 are electrically separated from each other by the third oxide film 208 and the third nitride film 209. Thus, an inter-gate breakdown voltage is improved, so that a leakage current is much less likely to be generated. Since a dielectric constant of a nitride film is about the double of a dielectric constant of an oxide film, an effective thickness of an interlevel film can be reduced. Therefore, excellent transfer efficiency can be ensured.

In this embodiment, as a gate insulating film located under each of the gate electrodes 204, 207 and 210, a two-layer structure (ON structure) including a thermally-oxidized film and a silicon nitride film is used. However, instead of the two-layer structure, a three-layer structure (ONO structure) in which a thermally-oxidized film or a low-pressure CVD oxide film is further formed on the silicon nitride film may be used. Specifically, after formation of the first nitride film 203 and before formation of the first gate electrodes 204, an oxide film may be formed on the first nitride film 203, after formation of the second nitride film 206 and before formation of the second gate electrodes 207, an oxide film may be formed on the second nitride film 206, and after formation of the third nitride film 209 and before formation of the third gate electrodes 210, an oxide film may be formed on the third nitride film 209.

According to this embodiment, each of a thickness of the second nitride film 206 newly formed according to the amount of reduction in film thickness of the first nitride film 203 and a thickness of the third nitride film 209 newly formed according to the amount of reduction in film thickness of the second nitride film 206 is not particularly limited but, for example, is about 2 nm or more and about 35 nm or less. Specifically, each of the amount of reduction in film thickness of the first nitride film 203 and the amount of reduction in film thickness of the second nitride film 206 may be predicted, for example, by a statistical technique and, on the basis of a result of the prediction, the respective thicknesses of the second nitride film 206 and the third nitride film 209 may be set. Alternatively, each of the amount of reduction in film thickness of the first nitride film 203 and the amount of reduction in film thickness of the second nitride film 206 may be actually measured and, on the basis of a result of the measurement, the respective thicknesses of the second nitride film 206 and the third nitride film 209 may be set.

This embodiment is directed to a solid state imaging device including transfer portions each having a three-layer gate structure. However, instead of this structure, this embodiment may be directed to a solid state imaging device including transfer portions each having a four- or more-layer gate structure.

### INDUSTRIAL APPLICABILITY

A solid state imaging device according to the present invention and a method for fabricating the solid state imaging device make it possible to achieve a solid state imaging device having excellent transfer efficiency and an excellent saturated charge amount and thus can be preferably used, specifically, for a solid state imaging device used in a camera-equipped cellular phone, a video camera, a digital still camera or the like or a line sensor used in a printer.

1. A solid state imaging device comprising:
a semiconductor substrate;
a first oxide film and a first nitride film formed over the semiconductor substrate so as to be stacked in this order;
a plurality of first gate electrodes arranged on the first nitride film so as to be spaced apart from one another with a predetermined distance therebetween;
a second oxide film formed so as to cover upper part and side walls of each said first gate electrode;
a second nitride film formed so as to cover the second oxide film and part of the first nitride film located between the first gate electrodes; and
a plurality of second gate electrodes formed on at least part of the second nitride film located between adjacent two of the first gate electrodes,
wherein each said second gate electrode is separated from an associated one of the first gate electrodes by the second oxide film and the second nitride film and is separated from the semiconductor substrate by the first oxide film, the first nitride film and the second nitride film.

2. The solid state imaging device of claim 1, wherein oxide films are provided between each said first gate electrode and the first nitride film and between each said second gate electrode and the second nitride film, respectively.

3. The solid state imaging device of claim 1, wherein a thickness of the second nitride film is adjusted so that a potential under each said first gate electrode and a potential under each said second gate electrode become the same.

4. The solid state imaging device of claim 1, wherein a total of respective thicknesses of parts of the first nitride film and the second nitride film located under each said second gate electrode is the same as a thickness of part of the first nitride film located under each said first gate electrode.

5. The solid state imaging device of claim 1, wherein part of the first nitride film located under each said first gate electrode and part of the first nitride film located under each said second gate electrode are a continuous film.

6. A solid state imaging device comprising:
a semiconductor substrate;
a first oxide film and a first nitride film formed over the semiconductor substrate so as to be stacked in this order;
a plurality of first gate electrodes arranged on the first nitride film so as to be spaced apart from one another with a predetermined distance therebetween;
a second oxide film formed so as to cover upper part and side walls of each said first gate electrode;
a second nitride film formed so as to cover the second oxide film and part of the first nitride film located between the first gate electrodes;
a plurality of second gate electrodes formed on at least part of the second nitride film located between adjacent two of the first gate electrodes, a third oxide film formed so as to cover upper part and side walls of each said second gate electrode;
a third nitride film formed so as to cover the third oxide film and part of the second nitride film located between the second gate electrodes; and
a plurality of third gate electrodes formed on at least part of the third nitride film located between adjacent two of the second gate electrodes,
wherein each said second gate electrode is separated from an associated one of the first gate electrodes by the second oxide film and the second nitride film and is separated from the semiconductor substrate by the first oxide film, the first nitride film and the second nitride film, and
wherein each said third gate electrode is separated from an associated one of the second gate electrodes by the third oxide film and the third nitride film and separated from the semiconductor substrate by the first oxide film, the first nitride film, the second nitride film and the third nitride film.

7. The solid state imaging device of claim 6, wherein oxide films are provided between each said first gate electrode and the first nitride film, between each said second gate electrode and the second nitride film and between each said third gate electrode and the third nitride film, respectively.

8. The solid state imaging device of claim 6, wherein a thickness of the third nitride film is adjusted so that a potential under each said first gate electrode, a potential under each said second gate electrode and a potential under each said third gate electrode become the same.

9. The solid state imaging device of claim 6, wherein a total of respective thicknesses of parts of the first nitride film, the second nitride film and the third nitride film located under each said third gate electrode is the same as a thickness of part of the first nitride film located under each said first gate electrode.

10. The solid state imaging device of claim 6, wherein part of the first nitride film located under each said first gate electrode, part of the first nitride film located under each said second gate electrode and part of the first nitride film located under each said third gate electrode are a continuous film.

11. A method for fabricating a solid state imaging device, the method comprising:
a first step of forming a first oxide film and a first nitride film over a semiconductor substrate so that the first oxide film and the first nitride film are stacked in this order;
a second step of forming, on the first nitride film, a plurality of first gate electrodes so that the first gate electrodes are arranged so as to be spaced apart from one another with a predetermined distance therebetween;
a third step of forming a second oxide film so that the second oxide film covers upper part and side walls of each said first gate electrode;
a fourth step of forming a second nitride film so that the second nitride film covers the second oxide film and part of the first nitride film located between the first gate electrodes; and
a fifth step of forming a plurality of second gate electrodes on at least part of the second nitride film located between adjacent two of the first gate electrodes.

12. The method of claim 11, further comprising:
before the second step, the step of forming an oxide film on the first nitride film; and
before the fifth step, the step of forming an oxide film on the second nitride film.

13. The method of claim 11, wherein a thickness of the second nitride film is adjusted so that a potential under each said first gate electrode and a potential under each said second gate electrode become the same.

14. The method of claim 11, wherein a thickness of the second nitride film is adjusted so that a total of respective thicknesses of parts of the first nitride film and the second nitride film located under each said second gate electrode is the same as a thickness of part of the first nitride film located under each said first gate electrode.

15. The method of claim 11, where a thickness of the second nitride film is 2 nm or more and 35 nm or less.

16. The method of claim 11, wherein in the second step, part of the first nitride film located outside each said first electrode is kept remaining.

17. A method for fabricating a solid state imaging device, the method comprising:
a first step of forming a first oxide film and a first nitride film over a semiconductor substrate so that the first oxide film and the first nitride film are stacked in this order;
a second step of forming, on the first nitride film, a plurality of first gate electrodes so that the first gate electrodes are arranged so as to be spaced apart from one another with a predetermined distance therebetween;
a third step of forming a second oxide film so that the second oxide film covers upper part and side walls of each said first gate electrode;
a fourth step of forming a second nitride film so that the second nitride film covers the second oxide film and part of the first nitride film located between the first gate electrodes;
a fifth step of forming a plurality of second gate electrodes on at least part of the second nitride film located between adjacent two of the first gate electrodes;
a sixth step of forming a third oxide film so that the third oxide film covers upper part and side walls of each said second gate electrode;
a seventh step of forming a third nitride film so that the third nitride film covers the third oxide film and part of the second nitride film located between the second gate electrodes; and
an eighth step of forming a plurality of third gate electrodes on at least part of the third nitride film located between adjacent two of the second gate electrodes.

18. The method of claim 17, further comprising:
before the second step, the step of forming an oxide film on the first nitride film;
before the fifth step, the step of forming an oxide film on the second nitride film; and
before the eighth step, the step of forming an oxide film on the third nitride film.

19. The method of claim 17, wherein a thickness of the third nitride film is adjusted so that a potential under each said first gate electrode, a potential under each said second gate electrode and a potential under each said third gate electrode become the same.

20. The method of claim 17, wherein a thickness of the third nitride film is adjusted so that a total of respective thicknesses of parts of the first nitride film, the second nitride film and the third nitride film located under each said third gate electrode is the same as a thickness of part of the first nitride film located under each said first gate electrode.

21. The method of claim 17, wherein a thickness of the third nitride film is 2 nm or more and 35 nm or less.

22. The method of claim 17, wherein in the second step, part of the first nitride film located outside each said first gate electrode is kept remaining, and wherein in the fifth step, part of the second nitride film located outside each second gate electrode is kept remaining.
